(19) United States
(12) Patent Application Publication
(10) Pub. No.: US 2026/0209641 A1
(43) Pub. Date: Jul. 23, 2026

(54) LIQUID DETERGENT, METHOD FOR CLEANING SUBSTRATE, AND METHOD FOR PRODUCING SEMICONDUCTOR ELEMENT

(71) Applicant: TOKYO OHKA KOGYO CO., LTD., Kawasaki-shi (JP)

(72) Inventors: Kohei Serizawa, Kawasaki-shi (JP); Choitsu Go, Kawasaki-shi (JP); Yukihisa Wada, Kawasaki-shi (JP)

(21) Appl. No.: 19/138,336

(22) PCT Filed: Nov. 29, 2023
(86) PCT No.: PCT/JP2023/042744

§ 371 Date: Jun. 12, 2025

(30) Foreign Application Priority Data
Dec. 28, 2022 (JP) 2022-211681

(51) Int. Cl. C11D 3/32; C11D 3/30

(52) U.S. Cl. CPC C11D 3/323; C11D 3/30; C11D 3/32

(57) ABSTRACT

A liquid detergent for removing an etching residue containing an inorganic substance, the liquid detergent including a compound represented by General Formula (a1) and at least of an amine and an ammonium compound other than the compound. In General Formula (a1), —R represents —NH₂ or —O—C(CH₃)₃. In such a liquid detergent, both removability of a dry etching residue and a property of reducing damage to a metal wiring are satisfactory, and thus safety is enhanced

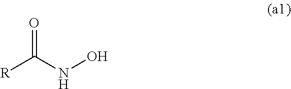

### TECHNICAL FIELD

The present invention relates to a liquid detergent, a method for cleaning a substrate, and a method for producing a semiconductor element.

Priority is claimed on Japanese Patent Application No. 2022-211681, filed Dec. 28, 2022, the content of which is incorporated herein by reference.

### BACKGROUND ART

In a wiring forming step, for example, a hard mask layer (HM layer) is formed on an interlayer insulating film in which a substrate, a metal wiring layer, and a silicon-based interlayer insulating film are laminated in this order, and the HM layer is etched to form an original form of a wiring pattern. The HM layer contains titanium nitride (TiN) or titanium oxide (TiOx).

Next, the interlayer insulating film is dry-etched using the etched HM layer as a mask to prepare a wiring pattern similar to that of the mask. Next, the HM layer is removed, and for example, a copper metal film is embedded into the interlayer insulating film having a wiring pattern shape by electroplating.

Inorganic substance-containing residues derived from the metal wiring layer and Ti-containing residues derived from the HM layer are attached to an element (substrate/metal wiring layer/interlayer insulating film/HM layer) after dry etching.

Dry etching residues are removed by a cleaning treatment in the related art. As a liquid detergent for removing dry etching residues, a liquid detergent containing a peroxide as a residue remover has been suggested (for example, see Patent Document 1). Alternatively, a liquid detergent containing hydroxylamine as a residue remover has been suggested.

### CITATION LIST

### Patent Document

Patent Document 1: PCT International Publication No. WO2016/076033

### SUMMARY OF INVENTION

### Technical Problem

The Ti-containing residues derived from the HM layer, which are attached to the element after the dry etching, are residues having high wet resistance and difficult to remove by a cleaning treatment. However, in a case where the liquid detergent described in Patent Document 1 is used, although the use of the liquid detergent is effective for the Ti-containing residues, there is a problem in that damage is caused to wirings of a substrate including a molybdenum wiring or a tungsten wiring due to the cleaning treatment.

In addition, in the liquid detergent containing hydroxylamine, it is desired to replace the residue remover in terms of the safety of hydroxylamine.

The present invention has been made in consideration of the above-described circumstances, and an object thereof is to provide a liquid detergent in which both removability of dry etching residues and a property of reducing damage to a metal wiring are satisfactory and safety is enhanced, and a method for cleaning a substrate and a method for producing a semiconductor element, which use the liquid detergent.

### Solution to Problem

In order to achieve the above-described object, the present invention has employed the following configurations.

According to a first aspect of the present invention, there is provided a liquid detergent for removing an etching residue containing an inorganic substance, the liquid detergent including: a compound (A) represented by General Formula (a1); and at least one base selected from the group consisting of an amine and an ammonium compound other than the compound (A).

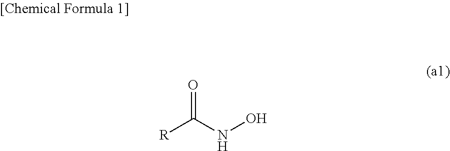

[In the formula, —R represents —NH₂ or —O—C(CH₃)₃.]

According to a second aspect of the present invention, there is provided a method for cleaning a substrate, including: a step (P1) of cleaning a substrate to which an etching residue containing an inorganic substance is attached, using the liquid detergent according to the first aspect.

According to a third aspect of the present invention, there is provided a method for producing a semiconductor element, including: a step (P1) of cleaning a substrate to which an etching residue containing an inorganic substance is attached, using the liquid detergent according to the first aspect.

### Advantageous Effects of Invention

According to the present invention, it is possible to provide a liquid detergent in which both removability of dry etching residues and a property of reducing damage to a metal wiring are satisfactory and safety is enhanced, and a method for cleaning a substrate and a method for producing a semiconductor element, which use the liquid detergent.

### BRIEF DESCRIPTION OF DRAWINGS

FIG. 1 A cross-sectional view showing an example of an element after dry etching, which is a cleaning target.

### DESCRIPTION OF EMBODIMENTS

### (First Aspect: Liquid Detergent)

A liquid detergent according to a first aspect of the present invention is a liquid detergent for removing an etching residue containing an inorganic substance.

The term “inorganic substance” here is a compound containing a metal atom, and examples thereof include a metal atom, a metal oxide, a metal nitride, a metal chloride, and a metal fluoride. Examples of the metal atom include Ti, Ta, Cu, Co, Ru, Al, W, Mo, Au, Ag, Fe, Ni, and Si. Examples of the metal oxide include TiOx, TaOx, CuOx, CoOx, RuOx, AlOx, WOx, MoOx, AuOx, AgOx, FeOx, NiOx, and SiOx. Examples of the metal nitride include TiNx, TaNx, CuNx, CoNx, RuNx, AlNx, WNx, MoNx, AuNx, AgNx, FeNx, NiNx, and SiNx. Examples of the metal chloride include TiClx, TaClx, CuClx, CoClx, RuClx, AlClx, WClx, MoClx, AuClx, AgClx, FeClx, NiClx, and SiClx. Examples of the metal fluoride include TiFx, TaFx, CuFx, CoFx, RuFx, AlFx, WFx, MoFx, AuFx, AgFx, FeFx, NiFx, and SiFx.

The etching residue is particularly a dry etching residue, and examples thereof include Ti-containing residues derived from a HM layer and inorganic substance-containing residues derived from a metal wiring layer, which are attached in a wiring process. The dry etching residue degrades the yield and electrical characteristics of a semiconductor, and thus is required to be removed before the subsequent step. The liquid detergent according to the present aspect is suitable for cleaning a substrate after dry etching is performed in the wiring process.

According to an embodiment of a liquid detergent of the present aspect, the liquid detergent contains a compound (A) represented by General Formula (a1) and at least one base selected from the group consisting of an amine and an ammonium compound other than the compound (A).

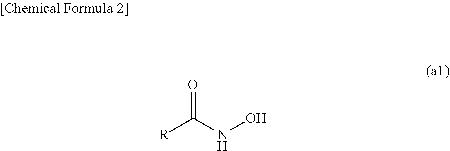

[In the formula, —R represents —NH₂ or —O—C(CH₃)₃.]

### <Compound (A)>

The liquid detergent according to the present embodiment contains a compound (A) (hereinafter, also referred to as “component (A)”) represented by General Formula (a1). In the liquid detergent, the component (A) is used as a residue remover.

The component (A) is a component having higher safety than hydroxylamine. In addition, the component (A) does not damage a metal wiring in the cleaning treatment.

In Formula (a1), in a case where —R represents —NH₂, the component (A) is hydroxyurea.

In Formula (a1), in a case where —R represents —O—C(CH₃)₃, the component (A) is N-(tert-butoxycarbonyl)hydroxylamine.

In the liquid detergent according to the present embodiment, the component (A) may be used alone or in combination of two kinds thereof.

The content of the component (A) in the liquid detergent of the present embodiment is not particularly limited, but is preferably 0.02% by mass or greater and 20% by mass or less, more preferably 0.2% by mass or greater and 18% by mass or less, and still more preferably 0.3% by mass or greater and 15% by mass or less with respect to the total mass of the liquid detergent.

In a case where the content of the component (A) is greater than or equal to the lower limits of the above-described preferable ranges, the removability of the dry etching residues is further enhanced in the cleaning treatment. Meanwhile, in a case where the content of the component (A) is less than or equal to the upper limits of the above-described preferable ranges, damage to the metal wiring is further suppressed.

### <Base>

The liquid detergent according to the present embodiment contains at least one base selected from the group consisting of an amine and an ammonium compound other than the compound (A). Since the liquid detergent contains the base, the pH of the liquid detergent can be increased, and the effect of removing residues of the component (A) is likely to be exhibited.

Examples of the amine other than the compound (A) in the base include ammonia (NH₃), a primary monoamine, a secondary monoamine, a tertiary monoamine, an alkanolamine, a secondary cyclic amine, a tertiary cyclic amine, a quaternary cyclic amine, a diamine, and a polyamine.

Examples of the primary monoamine include alkylamines such as methylamine, ethylamine, propylamine, n-butylamine, isopropylamine, and tert-butylamine; cycloalkylamines such as cyclopentylamine, cyclohexylamine, and cyclohexanemethylamine; and alkoxyamines such as methoxyethylamine, methoxypropylamine, methoxybutylamine, ethoxypropylamine, and propoxypropylamine.

Examples of the secondary monoamine include alkylamines such as dimethylamine, diethylamine, methylethylamine, dipropylamine, diisopropylamine, dibutylamine, diisobutylamine, and butylmethylamine; cycloalkylamines such as N,N-dicyclohexylamine and N-cyclopentylcyclohexanamine; and alkoxyamines such as methoxy(methylamine) and N-(2-methoxyethyl)ethylamine.

Examples of the tertiary monoamine include alkylamines such as trimethylamine, triethylamine, tripropylamine, tributylamine, triisobutylamine, dimethylethylamine, dimethylpropylamine, allyldiethylamine, dimethyl-n-butylamine, and diethylisopropylamine; and cycloalkylamines such as tricyclopentylamine and tricyclohexylamine.

Examples of the alkanolamine include monoethanolamine, diethanolamine, and triethanolamine.

Examples of the secondary cyclic amines include piperidines (compounds having a piperidine skeleton), pyrrolidines (compounds having a pyrrolidine skeleton), and morpholines (compounds having a morpholine skeleton). Examples of the piperidines which are secondary cyclic amines include piperidine, 2-pipecoline, 3-pipecoline, 4-pipecoline, 2,6-dimethylpiperidine, and 3,5-dimethylpiperidine. Examples of the pyrrolidines include pyrrolidine, 2-methylpyrrolidine, and 3-methylpyrrolidine. Examples of the morpholines include morpholine, 2-methylmorpholine, and 3-methylmorpholine.

Examples of the tertiary cyclic amines include piperidines, pyrrolidines, and morpholines. Examples of the piperidines include N-methylpiperidine. Examples of the pyrrolidines include N-methylpyrrolidine. Examples of the morpholines include N-methylmorpholine.

Examples of the quaternary cyclic amines include fluorides such as piperidines, pyrrolidines, and morpholines, chlorides, bromides, iodides, sulfates, hydrogensulfates, and acetates.

The diamine may be any of a primary diamine, a secondary diamine, or a tertiary diamine. Examples of the primary diamine include 2-(2-aminoethylamino)ethanol, ethylenediamine, butane 1,4-diamine, 1,3-propanediamine, 1,6-hexanediamine, and pentane-1,5-diamine. Examples of the secondary diamine include 2-methylpiperazine, 2,3-dimethylpiperazine, 2,5-dimethylpiperazine, N,N′-dimethylethanediamine, N,N′-dimethylpropanediamine, N,N′-diethylethylenediamine, N,N′-diethylpropanediamine, and N,N′-diisopropylethylenediamine. Examples of the tertiary diamine include 4-dimethylaminopyridine, N,N,N′,N′-tetramethylethylenediamine, N,N,N′,N′-tetraethylethylenediamine, N,N,N′,N′-tetramethyl-1,3-diaminopropane, N,N,N′,N′-tetramethyl-1,3-diaminobutane, N′,N′-tetramethyl-1,4-diaminobutane, N,N,N′,N′-tetramethylphenylenediamine, and 1,2-dipiperidinoethane.

The polyamine is a compound containing three or more amino groups, and a triamine is preferable. The polyamine may contain any of a primary amino group, a secondary amino group, or a tertiary amino group. Examples of the polyamine include spermine, spermidine, 3,3′-iminobis(propylamine), N,N-bis(3-aminopropyl)methylamine, N,N-bis(3-aminopropyl)butylamine, N-(3-aminopropyl)-N-dodecylpropane-1,3-diamine, diethylenetriamine, N,N,N′,N″,N″-pentamethyldiethylenetriamine, N,N,N′,N″,N″-pentamethyldipropylenetriamine, tris[2-(dimethylamino)ethyl]amine, 2-aminomethylpyrimidine, 1,4-bis(3-aminopropyl)piperazine, 1-amino-4-cyclopentylpiperazine, and 1-(2-pyridyl)piperazine.

Examples of the ammonium compound as the base include a hydroxide of a quaternary amine and a quaternary ammonium salt other than a hydroxide.

Examples of the hydroxide of the quaternary amine include tetramethylammonium hydroxide, tetraethylammonium hydroxide, tetrapropylammonium hydroxide, dimethylbis(2-hydroxyethyl)ammonium hydroxide, tetrabutylammonium hydroxide, tetrapentylammonium hydroxide, tris(2-hydroxyethyl)methylammonium hydroxide, choline, dimethyldiethylammonium hydroxide, tetraethanolammonium hydroxide, benzyltrimethylammonium hydroxide, benzyltriethylammonium hydroxide, and benzyltributylammonium hydroxide.

Examples of the quaternary ammonium salt other than the hydroxide include a fluoride, a chloride, a bromide, an iodide, a sulfate, a hydrogensulfate, and an acetate of quaternary ammonium. Specific examples of the quaternary ammonium salt include tetraethylammonium chloride, tetramethylammonium chloride, tetrapropylammonium chloride, tetrabutylammonium chloride, tetrapentylammonium chloride, tetraethylammonium bromide, tetramethylammonium bromide, tetrapropylammonium bromide, tetrabutylammonium bromide, tetrapentylammonium bromide, tetraethylammonium fluoride, tetramethylammonium fluoride, tetrapropylammonium fluoride, tetrabutylammonium fluoride, tetrapentylammonium fluoride, tetraethylammonium iodide, tetramethylammonium iodide, tetrapropylammonium iodide, tetrabutylammonium iodide, tetrapentylammonium iodide, tetraethylammonium hydrogensulfate, tetramethylammonium hydrogensulfate, tetrapropylammonium hydrogensulfate, and tetrabutylammonium hydrogensulfate.

In the liquid detergent according to the present embodiment, the base may be used alone or in combination of two or more kinds thereof.

Among the bases, at least one selected from the group consisting of ammonia, a hydroxide of a quaternary amine, an alkanolamine, and a triamine is preferably used, and at least one selected from the group consisting of ammonia, tetramethylammonium hydroxide, tetraethylammonium hydroxide, an alkanolamine, and a triamine is more preferably used.

From the viewpoint of the removability of the dry etching residues, it is preferable to use at least one selected from the group consisting of ammonia and a triamine as the base and particularly preferable to use ammonia.

The content of the base in the liquid detergent of the present embodiment is not particularly limited, but is preferably 0.003% by mass or greater and 15% by mass or less, more preferably 0.03% by mass or greater and 13% by mass or less, still more preferably 0.2% by mass or greater and 12% by mass or less, and particularly preferably 0.5% by mass or greater and 10% by mass or less with respect to the total mass of the liquid detergent.

In a case where the content of the base is greater than or equal to the lower limits of the above-described preferable ranges, the removability of the dry etching residues is further enhanced in the cleaning treatment. Meanwhile, in a case where the content of the base is less than or equal to the upper limits of the above-described preferable ranges, the effect of the combined use with the component (A) is likely to be obtained.

In the liquid detergent of the present embodiment, the content of the base is preferably 15 to 5000 parts by mass, more preferably 20 to 2500 parts by mass, and still more preferably 50 to 1000 parts by mass with respect to 100 parts by mass of the compound (A).

In a case where the content of the base is greater than or equal to the lower limits of the above-described preferable ranges with respect to 100 parts by mass of the compound (A), the removability of the dry etching residues and the property of reducing damage to the metal wiring in the cleaning treatment are likely to be enhanced. Meanwhile, in a case where the content of the base is less than or equal to the upper limits of the above-described preferable ranges, the effect of the combined use with the component (A) is likely to be obtained.

### <Solvent>

It is preferable that the liquid detergent of the present embodiment contains water as a solvent.

Water may contain a trace amount of components that are unavoidably mixed. As water that may be used in the liquid detergent of the present embodiment, water subjected to a purification treatment, such as distilled water, ion exchange water, or ultrapure water is preferable, and ultrapure water typically used in the manufacture of a semiconductor is more preferable.

Water can be blended into the liquid detergent according to the present embodiment such that the total content of the component (A), the component (B), and the following optional components blended as necessary reaches 100% by mass, that is, the content of water is the remaining amount.

The liquid detergent according to the present embodiment may contain the following organic solvent in addition to water as a solvent.

### <Optional Components>

The liquid detergent of the present embodiment may include optional components in addition to the (A) component and the (B) component. Examples of the optional components include an anticorrosive agent, a buffer, an organic solvent, a surfactant, and a pH adjuster.

### <<Anticorrosive Agent>>

The liquid detergent of the present embodiment may contain an anticorrosive agent.

Examples of the anticorrosive agent include compounds having a nitrogen-containing heterocyclic ring such as a triazole ring, an imidazole ring, a pyridine ring, a phenanthroline ring, a tetrazole ring, a pyrazole ring, a pyrimidine ring, or a purine ring.

### <<Buffer>>

The liquid detergent according to the present embodiment may contain a buffer. The buffer is a compound having an action of suppressing a change in the pH of a liquid detergent.

The buffer is not particularly limited as long as the buffer is a compound having a pH buffering capacity. As the buffer, for example, a compound with a pKa of 6 to 11 can be used.

Examples of the buffer include a Good's buffer. Example of the Good's buffer include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl)methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl)piperazine-1-(2-hydroxypropane-3-sulfonic acid) (HEPSO), and 4-(2-hydroxyethyl)-1-piperazinepropanesulfonic acid (EPPS).

The liquid detergent of the present embodiment may not contain the buffer, and may not contain one or more of the compounds described as specific examples of the buffer.

### <<Organic Solvent>>

The liquid detergent according to the present embodiment may contain an organic solvent within a range where the effects of the present invention are not impaired. A water-soluble organic solvent is preferable as the organic solvent. In a case where the liquid detergent contains an organic solvent, organic residues such as polymers are likely to be removed.

Examples of the water-soluble organic solvent include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, 2-methyl-2,4-pentanediol, and 3-methoxy-3-methyl-1-butanol; dimethyl sulfoxide; ethers such as ethylene glycol dimethyl ether, diethylene glycol dimethyl ether, triethylene glycol dimethyl ether, tetraethylene glycol dimethyl ether, and propylene glycol dimethyl ether; and morpholines such as N-methylmorpholine N-oxide.

The organic solvent may be used alone or in combination of two or more kinds thereof.

In a case where the liquid detergent of the present embodiment contains the organic solvent, the content of the organic solvent is preferably in a range of 0.05% to 50% by mass, more preferably in a range of 0.1% to 30% by mass, still more preferably in a range of 0.1% to 20% by mass, and particularly preferably in a range of 0.1% to 10% by mass with respect to the total amount of water and organic solvent.

The liquid detergent according to the present embodiment may not contain the organic solvent or the water-soluble organic solvent, and may not contain one or more of the compounds described as specific examples of the water-soluble organic solvent.

### <<Surfactant>>

The liquid detergent of the present embodiment may contain a surfactant, for example, for the purpose of adjusting the wettability of the liquid detergent to a substrate. Examples of the surfactant include a nonionic surfactant, an anionic surfactant, a cationic surfactant, and an amphoteric surfactant.

Examples of the nonionic surfactant include polyalkylene oxide alkylphenyl ether-based surfactants, polyalkylene oxide alkyl ether-based surfactants, block polymer-based surfactants consisting of polyethylene oxide and polypropylene oxide, polyoxyalkylene distyrenated phenyl ether-based surfactants, polyalkylene tribenzylphenyl ether-based surfactants, and acetylene polyalkylene oxide-based surfactants.

Examples of the anionic surfactant include alkylsulfonic acids, alkylbenzenesulfonic acids, alkylnaphthalenesulfonic acids, alkyldiphenyl ether sulfonic acids, fatty acid amidosulfonic acids, polyoxyethylene alkyl ether carboxylic acids, polyoxyethylene alkyl ether acetic acids, polyoxyethylene alkyl ether propionic acids, alkyl phosphonic acids, and fatty acid salts. Examples of “salts” include ammonium salts, sodium salts, potassium salts, and tetramethylammonium salts.

Examples of cationic surfactant include alkylpyridinium-based surfactants and quaternary ammonium salt-based surfactants.

Examples of the amphoteric surfactant include betaine type surfactants, amino acid type surfactants, imidazoline type surfactants, and amine oxide type surfactants.

These surfactants are generally commercially available. The surfactant may be used alone or in combination of two or more kinds thereof.

In a case where the liquid detergent of the present embodiment contains the surfactant, the content of the surfactant is not particularly limited, but is, for example, preferably in a range of 0.0001% by mass to 5% by mass, more preferably in a range of 0.0002% by mass to 3% by mass, still more preferably in a range of 0.002% by mass to 1% by mass, and particularly preferably in a range of 0.002% by mass to 0.2% by mass with respect to the total mass of the liquid detergent.

The liquid detergent according to the present embodiment may not contain one or more selected from the group consisting of a nonionic surfactant, an anionic surfactant, a cationic surfactant, and an amphoteric surfactant, and may not contain one or more of the compounds described as the surfactant. The liquid detergent of the present embodiment may not contain the surfactant.

### <<pH Adjuster>>

The liquid detergent according to the present embodiment may contain a pH adjuster in order to adjust the pH to a desired value. As the pH adjuster, an inorganic acid, an organic acid, an organic basic compound, or an inorganic basic compound can be appropriately used.

### <<Impurities and the Like>>

The liquid detergent of the present embodiment may include metal impurities including metal atoms such as an Fe atom, a Cr atom, an Ni atom, a Zn atom, a Ca atom, and a Pb atom.

The total content of the metal atoms in the liquid detergent of the present embodiment is preferably 100 ppt by mass or less with respect to the total mass of the liquid detergent. The lower limit of the total content of the metal atoms is preferably as low as possible, but may be, for example, 0.001 ppt by mass or greater. The total content of the metal atoms may be, for example, 0.001 ppt by mass to 100 ppt by mass. By setting the total content of the metal atoms to less than or equal to the preferable upper limit, the defect suppressing properties and the residue suppressing properties of the liquid detergent are improved. It is considered that in a case where the total content of the metal atoms is set to greater than or equal to the preferable lower limit, the metal atoms are less likely to be released in the system and less likely to adversely affect the production yield of the entire object to be cleaned.

The content of the metal impurities can be adjusted, for example, by a purification treatment such as filtering. A purification treatment such as filtering may be performed on a part or all of the raw materials before preparing the liquid detergent, or may be performed after preparing the liquid detergent.

The liquid detergent of the present embodiment may include, for example, organic substance-derived impurities (organic impurities). The total content of the organic impurities in the liquid detergent of the present embodiment is preferably 5,000 ppm by mass or less. The lower limit of the content of the organic impurities is preferably as low as possible, and the lower limit may be, for example, greater than or equal to 0.1 ppm by mass. The total content of the organic impurities is, for example, 0.1 ppm by mass to 5,000 ppm by mass.

The liquid detergent of the present embodiment may include, for example, objects to be counted having a size that can be counted by a light scattering type in-liquid particle counter. The size of the object to be counted is, for example, 0.04 μm or greater. The number of the objects to be counted in the liquid detergent of the present embodiment is, for example, 1,000 or less per mL of the liquid detergent, and the lower limit is, for example, 1 or greater. It is considered that in a case where the number of the objects to be counted in the liquid detergent is within the range, the metal corrosion suppressing effect of the liquid detergent is improved.

The organic impurities and/or the objects to be counted may be added to the liquid detergent, or may be unavoidably mixed in the liquid detergent during a step of producing the liquid detergent. Examples of the cases where organic impurities are unavoidably mixed in the step of producing the liquid detergent include a case where raw materials (for example, an organic solvent) used in the production of the liquid detergent contain organic impurities and a case where organic impurities are mixed (for example, contamination) from the external environment in the step of producing the liquid detergent, but the examples are not limited thereto.

In a case where the objects to be counted are added to the liquid detergent, the existence ratio may be adjusted for each specific size in consideration of the surface roughness and the like of a cleaning target.

### <pH of Liquid Detergent>

The pH of the liquid detergent of the present embodiment, which is measured at 23° C., is preferably 8.0 or greater and more preferably 8.0 or greater and less than 14.0.

In a case where the pH of the liquid detergent is greater than or equal to the lower limits of the above-described preferable ranges, the removability of the dry etching residues is likely to be enhanced in the cleaning treatment.

The pH of the liquid detergent is a value measured at 23° C. with a pH meter under a condition of a normal pressure (1 atm).

Suitable examples of the liquid detergent according to the present embodiment include the following embodiments (1-1) and (1-2).

Embodiment (1-1): a liquid detergent containing hydroxyurea (in a case where —R in Formula (a1) represents —NH₂), at least one base selected from the group consisting of an amine and an ammonium compound other than the compound (A), and water

Embodiment (1-2): a liquid detergent containing N-(tert-butoxycarbonyl)hydroxylamine (in a case where —R in Formula (a1) represents —O—C(CH₃)₃), at least one base selected from the group consisting of an amine and an ammonium compound other than the compound (A), and water

In regard to embodiment (1-1):

The liquid detergent of the embodiment (1-1) contains hydroxyurea, at least one base selected from the group consisting of an amine and an ammonium compound other than the compound (A), and water as a remaining amount, and may contain optional components as necessary.

Among the bases, at least one selected from the group consisting of ammonia, a hydroxide of a quaternary amine, an alkanolamine, and a triamine is preferably used, and at least one selected from the group consisting of ammonia, tetraethylammonium hydroxide, monoethanolamine, and diethylenetriamine is more preferably used.

The content of the hydroxyurea in the liquid detergent according to the embodiment (1-1) is preferably 0.02% by mass or greater and 20% by mass or less, more preferably 0.2% by mass or greater and 15% by mass or less, and still more preferably 0.5% by mass or greater and 10% by mass or less with respect to the total mass of the liquid detergent.

The content of the base in the liquid detergent according to the embodiment (1-1) is preferably 0.003% by mass or greater and 15% by mass or less, more preferably 0.03% by mass or greater and 13% by mass or less, still more preferably 0.2% by mass or greater and 12% by mass or less, and particularly preferably 0.5% by mass or greater and 10% by mass or less with respect to the total mass of the liquid detergent.

In the liquid detergent of the embodiment (1-1), the content of the base is preferably in a range of 15 to 5000 parts by mass, more preferably in a range of 20 to 2500 parts by mass, and still more preferably in a range of 50 to 1000 parts by mass with respect to 100 parts by mass of the hydroxyurea.

The pH of the liquid detergent of the embodiment (1-1), which is measured at 23° C., is preferably 9.0 or greater, more preferably 9.5 or greater and less than 14.0, and still more preferably 10.0 or greater and 13.6 or less.

In regard to embodiment (1-2):

The liquid detergent of the embodiment (1-2) contains N-(tert-butoxycarbonyl)hydroxylamine, at least one base selected from the group consisting of an amine and an ammonium compound other than the compound (A), and water as a remaining amount, and may contain optional components as necessary.

Among the bases, at least one selected from the group consisting of ammonia, a hydroxide of a quaternary amine, an alkanolamine, and a triamine is preferably used, at least one selected from the group consisting of ammonia, a hydroxide of a quaternary amine, and an alkanolamine is more preferably used, and at least one selected from the group consisting of ammonia, tetraethylammonium hydroxide, and monoethanolamine is still more preferably used.

The content of N-(tert-butoxycarbonyl)hydroxylamine in the liquid detergent of the embodiment (1-2) is preferably 0.02% by mass or greater and 15% by mass or less, more preferably 0.3% by mass or greater and 10% by mass or less, and still more preferably 0.4% by mass or greater and 5% by mass or less with respect to the total mass of the liquid detergent.

The content of the base in the liquid detergent according to the embodiment (1-2) is preferably 0.003% by mass or greater and 15% by mass or less, more preferably 0.03% by mass or greater and 13% by mass or less, still more preferably 0.2% by mass or greater and 12% by mass or less, and particularly preferably 0.5% by mass or greater and 10% by mass or less with respect to the total mass of the liquid detergent.

In the liquid detergent of the embodiment (1-2), the content of the base is preferably in a range of 15 to 5000 parts by mass, more preferably in a range of 20 to 2500 parts by mass, and still more preferably in a range of 50 to 1000 parts by mass with respect to 100 parts by mass of N-(tert-butoxycarbonyl)hydroxylamine.

The pH of the liquid detergent of the embodiment (1-2), which is measured at 23° C., is preferably 8.0 or greater, more preferably 8.5 or greater and less than 14.0, and still more preferably 9.0 or greater and 13.8 or less.

A method of storing the liquid detergent of the present embodiment is not particularly limited, and storage containers known in the related art can be used. In order to ensure the stability of the liquid detergent, a void ratio in a container in a case of storing the liquid detergent in the container and/or a type of gas filling the voids may be appropriately set. For example, the void ratio in the storage container may be approximately in a range of 0.01% to 30% by volume.

The liquid detergent of the present embodiment can be used, for example, in the section of (Second aspect: method for cleaning substrate) described below.

According to the liquid detergent of the present embodiment described above, since the liquid detergent contains the compound (A) represented by General Formula (a1) and at least one base selected from the group consisting of an amine and an ammonium compound other than the compound (A), in a case of an element to which etching residues containing an inorganic substance are attached, the etching residues derived from the HM layer can be satisfactorily cleaned and removed while the metal wiring layer is protected. Therefore, the present invention can be suitably applied to the cleaning of a substrate (a substrate or an element) after the dry etching is performed in a wiring process.

In addition, since the compound (A) is employed as a residue remover in the liquid detergent according to the present embodiment, the safety of the liquid detergent is further enhanced as compared with hydroxylamine used for general purposes in the related art.

Further, the hydroxylamine is an explosive compound, and is a substance that belongs to Class 5 hazardous materials (self-reactive substance) in the Fire Service Act and is designated as a deleterious substance by the Poisonous and Deleterious Substances Control Act.

### (Second Aspect: Method for Cleaning Substrate)

A method for cleaning a substrate according to a second aspect of the present invention includes a step (P1) of cleaning a substrate to which etching residues containing an inorganic substance are attached, using the liquid detergent according to the first aspect.

In the cleaning method according to the present aspect, the substrate to which etching residues as the cleaning target are attached is formed of the single substrate and an element provided with the substrate.

The element may be an element after a metal wiring layer is subjected to dry etching by, for example, a semi-damascene process. Further, the element may be an element in which a metal wiring layer is exposed after a Si-containing layer (for example, a Si-containing interlayer insulating film) is subjected to dry etching in a wiring process. Further, the element may be a substrate in which a metal wiring layer is exposed after a CMP step in a wiring process.

Suitable examples of the metal wiring layer include a layer containing at least one metal selected from the group consisting of molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, and thallium.

Hereinafter, an embodiment of the method for cleaning a substrate according to the present aspect will be described with reference to the accompanying drawing.

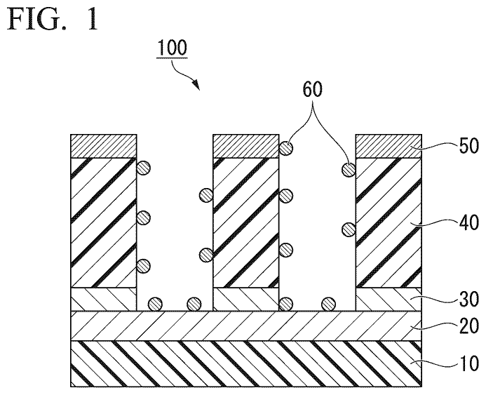

FIG. 1 shows an example of an element (substrate/metal wiring layer/interlayer insulating film/HM layer) after dry etching, which is a cleaning target.

An element 100 shown in FIG. 1 is formed such that a substrate 10, a metal wiring layer 20, an etching stop layer 30, and an interlayer insulating film 40 are laminated in this order and a hard mask layer (HM layer) 50 is formed on the interlayer insulating film 40.

The element 100 is an element that has been subjected to dry etching in the wiring process, that is, an element in a state after the interlayer insulating film 40 is dry-etched using the HM layer 50 on which an original form of a wiring pattern has been formed by dry etching, as a mask. Dry etching residues 60 are attached to the side surfaces of the HM layer 50 and the interlayer insulating film 40.

In space portions between the interlayer insulating films 40 having a wiring pattern shape, the metal wiring layer 20 is exposed, and the dry etching residues 60 are also attached to the exposed metal wiring layer 20.

The substrate 10 is formed of a material such as silicon, amorphous silicon, or glass.

The metal wiring layer 20 is a wiring layer consisting of metals such as molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, and thallium.

The interlayer insulating film 40 consists of silicon-based materials such as SiO₂, SiN, and SiOC.

The HM layer 50 is formed of a titanium-based material such as titanium nitride (TiN) or titanium oxide (TiOx).

The dry etching residues 60 are mainly Ti-containing residues containing a titanium-based material derived from the HM layer 50.

[Cleaning step (P1)]

The present step (P1) is a step of cleaning the element 100 after the element is dry-etched in the wiring process using the liquid detergent according to the first aspect.

The cleaning method is not particularly limited, and a known cleaning method can be used.

In a case where the liquid detergent is brought into contact with the element 100 which is a cleaning target, the liquid detergent may be diluted 2 to 2000 times to obtain a diluted liquid, and an operation of cleaning the element 100 using the diluted liquid may be performed.

Examples of the cleaning operation include a method of continuously coating the element 100 rotating at a constant speed with the liquid detergent (rotation coating method), a method of dipping the element 100 in the liquid detergent for a certain time (dip method), and a method of spraying the liquid detergent to the surface of the element 100 (spraying method).

The temperature at which the cleaning treatment is performed is not particularly limited. The cleaning treatment is performed under a temperature condition of preferably 10° C. to 80° C., and the temperature may be in a range of 20° C. to 75° C. or 40° C. to 70° C.

The removability of the etching residues is improved by increasing the temperature of the liquid detergent, but the temperature of the liquid detergent can be appropriately selected in consideration of suppression of a change in the composition of the liquid detergent, workability, the safety, the cost, and the like.

As the cleaning time, a time sufficient for removing etching residues, impurities, and the like attached to the surface of the element 100 can be appropriately selected. The cleaning time is, for example, in a range of 10 seconds to 30 minutes, and may be in a range of 20 seconds to 15 minutes, in a range of 30 seconds to 10 minutes, or in a range of 30 seconds to 5 minutes.

According to the cleaning method of the present embodiment described above, since the element 100 to which the dry etching residues 60 are attached is cleaned by using the liquid detergent according to the first aspect, the dry etching residues 60 derived from the HM layer 50 can be satisfactorily cleaned and removed while damage to the metal wiring layer 20 is suppressed. Further, according to the cleaning method of the present embodiment, damage to the interlayer insulating film 40 can also be suppressed.

In addition, since the compound (A) is employed as a residue remover in the liquid detergent, a semiconductor element and the like can be more safely manufactured as compared with hydroxylamine used for general purposes in the related art.

### (Third Aspect: Method for Producing Semiconductor Element)

A method for producing a semiconductor element according to a third aspect of the present invention includes a step (P1) of cleaning a substrate to which etching residues containing an inorganic substance are attached, using the liquid detergent according to the first aspect.

A production method including the step (P1) and optional steps is an exemplary example of an embodiment of the method for producing a semiconductor element.

In the production method according to the present embodiment, the step (P1) can be performed in the same manner as the method described in the section of [Cleaning step (P1)] of (second aspect: method for cleaning substrate) described above.

Examples of the optional steps include a hard mask layer etching step, a wiring layer dry etching step, and a contact etching step, before the step (P1). Further, examples of the optional steps include known steps performed in a case of manufacturing a semiconductor element, such as formation steps (such as layer formation, etching other than the above-described etching treatment, chemical-mechanical polishing, transformation) of capacitor formation, channel formation, High-K/metal gate formation, each structure such as a metal wiring, a gate structure, a source structure, a drain structure, an insulating layer, a ferromagnetic layer, or a nonmagnetic layer, a resist film forming step, a light exposure step, a development step, a heat treatment step, and an inspection step.

According to the method for producing a semiconductor element of the present embodiment described above, since the method includes the step (P1) of cleaning a substrate to which etching residues containing an inorganic substance are attached, using the liquid detergent according to the first aspect, the etching residues can be satisfactorily removed while damage to the metal wiring is suppressed. In this manner, the electrical characteristics of a semiconductor element to be manufactured can be improved.

### EXAMPLES

Hereinafter, the present invention will be described in more detail based on examples, but the present invention is not limited to these examples.

Components used in examples and comparative examples are shown below.

### Residue Remover

(A)-1: hydroxyurea
(A)-2: N-Boc-HA (N-(tert-butoxycarbonyl)hydroxylamine)
(A)-3: hydroxylamine
(A)-4: hydrogen peroxide

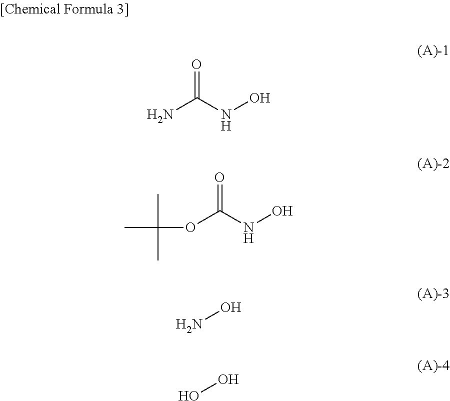

### Base

(B)-1: ammonia
(B)-2: tetraethylammonium hydroxide
(B)-3: monoethanolamine
(B)-4: diethylenetriamine

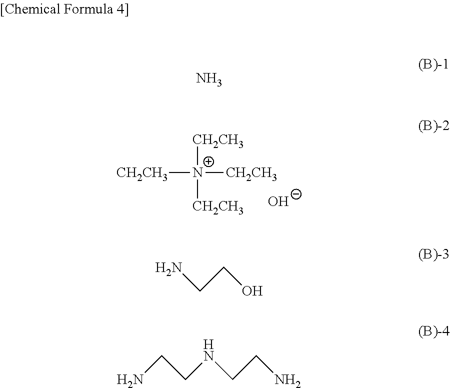

### pH Adjuster

(C)-1: citric acid

### Solvent

(S)-1: water
(S)-2: glycerin

### <Preparation of Liquid Detergent>

### Examples 1 to 13 and Comparative Examples 1 to 4; Examples 14 to 25 and Comparative Examples 5 to 8

Each component listed in Tables 1 and 2 was used to prepare a liquid detergent of each example.

In Tables 1 and 2, each abbreviation has the meaning described above. The numerical values in the brackets denote the proportion (% by mass) of the content of each component with respect to the total mass of the liquid detergent.

### [pH of Liquid Detergent]

The pH of the liquid detergent was measured using a pH meter (portable pH meter D-73S, manufactured by Horiba, Ltd.) under a temperature condition of 23° C. The results are listed in Tables 1 and 2 in the columns of “pH (23° C.)”.

### Evaluation

The removability of etching residues and the property of reducing damage to metals were evaluated for the liquid detergent of each example using the etching rate as an index in the following manner.

### [Measurement of Etching Rate]

As the substrate, a substrate obtained by forming a titanium nitride (TiN) film having a film thickness of 50 nm, a tungsten (W) film having a film thickness of 100 nm, and a molybdenum (Mo) film having a film thickness of 50 nm on a 12-inch silicon substrate by a PVD method was used.

The substrate on which the film had been formed was cut into a size of 2 cm×2 cm to produce a wafer coupon.

100 mL of the liquid detergent of each example was put into a beaker having a volume of 200 mL and heated to a predetermined treatment temperature listed in the table, and the cut wafer coupon was dipped in the liquid detergent. During the dipping of the wafer coupon in the liquid detergent, the liquid detergent was stirred at a predetermined treatment temperature listed in the table and 300 rpm. The wafer coupon was dipped for 60 minutes, taken out from the liquid detergent, cleaned with water at room temperature for 30 seconds, and dried by blowing nitrogen.

The film thicknesses of the wafer coupon before and after the dipping in the liquid detergent were measured.

The film thicknesses of the wafer coupons each having a TiN film, a W film, and a Mo film were measured using an X-ray fluorescence spectrometer (ZSX Primus IV, manufactured by Rigaku Corporation).

Next, the etching rate was calculated from a change in the film thickness of the TiN film, the W film, and the Mo film before and after the cleaning treatment.

### Evaluation of Removability of Etching Residues

The removability of the etching residue was evaluated according to the following evaluation criteria, using the etching rate of the liquid detergent with respect to the TiN film as an index. The results are listed in Tables 1 and 2.

In a case where the value of the etching rate increases, this indicates that the removability of the etching residues is more excellent.

### Evaluation Criteria for Removability of Etching Residues

A: The etching rate of the liquid detergent with respect to the TiN film was greater than 0.4×10⁻¹⁰ m/min.
B: The etching rate of the liquid detergent with respect to the TiN film was 0.1×10⁻¹⁰ m/min or greater and 0.4×10⁻¹⁰ m/min or less.
C: The etching rate of the liquid detergent with respect to the TiN film was less than 0.1×10⁻¹⁰ m/min.

### Evaluation of Property of Reducing Damage to Metal

The property of reducing damage to metals was evaluated using the etching rate of the liquid detergent with respect to the W film (W E.R.) and the etching rate of the liquid detergent with respect to the Mo film (Mo E.R.) as an index. The values of each etching rate are listed in Tables 1 and 2.

In a case where the value of each etching rate decreases, this indicates that the damage to the metals (for example, the metal wiring) decreases.

TABLE 1

| | Composition of liquid | | | | | | | | Property of reducing | |
|---|---|---|---|---|---|---|---|---|---|---|
| | detergent/% by mass | | | | | | Treatment | Removability | damage to metal | |
| | Residue | | pH | | | pH | temperature | of etching | W E.R. | Mo E.R. |
| | remover | Base | adjuster | Solvent | | (23° C.) | [° C.] | residues | [10⁻¹⁰ m/min] | [10⁻¹⁰ m/min] |
| Comparative | (A)-4 | (B)-1 | — | (S)-1 | — | 10.6 | 25 | A | 67.9 | 186.3 |
| Example 1 | [0.6] | [0.6] | | [remaining | | | | | | |
| | | | | amount] | | | | | | |
| Comparative | — | (B)-1 | — | (S)-1 | — | 11.8 | 60 | C | 3.0 | 2.5 |
| Example 2 | | [2] | | [remaining | | | | | | |
| | | | | amount] | | | | | | |
| Comparative | (A)-3 | — | — | (S)-1 | — | 9.7 | 60 | A | 2.7 | 1.8 |
| Example 3 | [1] | | | [remaining | | | | | | |
| | | | | amount] | | | | | | |
| Comparative | (A)-1 | — | — | (S)-1 | — | 5.8 | 60 | C | 0.20 | 0.30 |
| Example 4 | [1] | | | [remaining | | | | | | |
| | | | | amount] | | | | | | |
| Example 1 | (A)-1 | (B)-1 | — | (S)-1 | — | 10.7 | 60 | A | 2.1 | 4.7 |
| | [1] | [2] | | [remaining | | | | | | |
| | | | | amount] | | | | | | |
| Example 2 | (A)-1 | (B)-1 | — | (S)-1 | — | 11.1 | 60 | A | 3.0 | 1.8 |
| | [0.3] | [2] | | [remaining | | | | | | |
| | | | | amount] | | | | | | |
| Example 3 | (A)-1 | (B)-1 | — | (S)-1 | — | 11.0 | 60 | A | 2.9 | 1.9 |
| | [0.4] | [2] | | [remaining | | | | | | |
| | | | | amount] | | | | | | |
| Example 4 | (A)-1 | (B)-1 | — | (S)-1 | — | 10.9 | 60 | A | 0 | 3.5 |
| | [0.5] | [2] | | [remaining | | | | | | |
| | | | | amount] | | | | | | |
| Example 5 | (A)-1 | (B)-1 | — | (S)-1 | — | 10.4 | 60 | A | 3.2 | 2.8 |
| | [7.6] | [2] | | [remaining | | | | | | |
| | | | | amount] | | | | | | |
| Example 6 | (A)-1 | (B)-2 | — | (S)-1 | — | 10.9 | 60 | A | 4.3 | 5.5 |
| | [1] | [1] | | [remaining | | | | | | |
| | | | | amount] | | | | | | |
| Example 7 | (A)-1 | (B)-3 | — | (S)-1 | — | 10.6 | 60 | B | 1.1 | 0.80 |
| | [1] | [3] | | [remaining | | | | | | |
| | | | | amount] | | | | | | |
| Example 8 | (A)-1 | (B)-4 | — | (S)-1 | — | 10.3 | 60 | A | 0.70 | 0.70 |
| | [1] | [1] | | [remaining | | | | | | |
| | | | | amount] | | | | | | |
| Example 9 | (A)-1 | (B)-1 | (C)-1 | (S)-1 | — | 9.1 | 60 | B | 2.0 | 1.3 |
| | [1] | [2] | [5.5] | [remaining | | | | | | |
| | | | | amount] | | | | | | |
| Example 10 | (A)-1 | (B)-1 | — | (S)-1 | — | 10.0 | 60 | A | 2.3 | 4.3 |
| | [1] | [0.2] | | [remaining | | | | | | |
| | | | | amount] | | | | | | |
| Example 11 | (A)-1 | (B)-2 | — | (S)-1 | — | 12.9 | 60 | A | 0 | 0.90 |
| | [1] | [3] | | [remaining | | | | | | |
| | | | | amount] | | | | | | |
| Example 12 | (A)-1 | (B)-2 | — | (S)-1 | — | 13.6 | 60 | A | 2.1 | 0.50 |
| | [1] | [10] | | [remaining | | | | | | |
| | | | | amount] | | | | | | |
| Example 13 | (A)-1 | (B)-1 | — | (S)-1 | (S)-2 | 10.7 | 60 | A | 5.5 | 2.4 |
| | [1] | [2] | | [remaining | [10] | | | | | |
| | | | | amount] | | | | | | |

TABLE 2

| | Composition of liquid | | | | | | | Property of reducing | |
|---|---|---|---|---|---|---|---|---|---|
| | detergent/% by mass | | | | | Treatment | Removability | damage to metal | |
| | Residue | | pH | | pH | temperature | of etching | W E.R. | Mo E.R. |
| | remover | Base | adjuster | Solvent | (23° C.) | [° C.] | residues | [10⁻¹⁰ m/min] | [10⁻¹⁰ m/min] |
| Comparative | (A)-4 | (B)-1 | — | (S)-1 | 10.6 | 25 | A | 67.9 | 186.3 |
| Example 5 | [0.6] | [0.6] | | [remaining | | | | | |
| | | | | amount] | | | | | |
| Comparative | — | (B)-1 | — | (S)-1 | 11.8 | 60 | C | 3.0 | 2.5 |
| Example 6 | | [2] | | [remaining | | | | | |
| | | | | amount] | | | | | |
| Comparative | (A)-3 | — | — | (S)-1 | 9.7 | 60 | A | 2.7 | 1.8 |
| Example 7 | [1] | | | [remaining | | | | | |
| | | | | amount] | | | | | |
| Comparative | (A)-2 | — | — | (S)-1 | 6.7 | 60 | C | 0.50 | 0.30 |
| Example 8 | [1] | | | [remaining | | | | | |
| | | | | amount] | | | | | |
| Example 14 | (A)-2 | (B)-1 | — | (S)-1 | 10.9 | 60 | A | 1.0 | 7.6 |
| | [1] | [2] | | [remaining | | | | | |
| | | | | amount] | | | | | |
| Example 15 | (A)-2 | (B)-1 | — | (S)-1 | 10.9 | 60 | B | 1.6 | 3.8 |
| | [0.3] | [2] | | [remaining | | | | | |
| | | | | amount] | | | | | |
| Example 16 | (A)-2 | (B)-1 | — | (S)-1 | 11.2 | 60 | A | 1.5 | 4.1 |
| | [0.4] | [2] | | [remaining | | | | | |
| | | | | amount] | | | | | |
| Example 17 | (A)-2 | (B)-1 | — | (S)-1 | 11.0 | 60 | A | 1.1 | 5.9 |
| | [0.5] | [2] | | [remaining | | | | | |
| | | | | amount] | | | | | |
| Example 18 | (A)-2 | (B)-1 | — | (S)-1 | 10.4 | 60 | A | 2.8 | 3.1 |
| | [13.3] | [5] | | [remaining | | | | | |
| | | | | amount] | | | | | |
| Example 19 | (A)-2 | (B)-2 | — | (S)-1 | 12.3 | 60 | A | 0 | 0.90 |
| | [1] | [1] | | [remaining | | | | | |
| | | | | amount] | | | | | |
| Example 20 | (A)-2 | (B)-3 | — | (S)-1 | 10.7 | 60 | A | 0 | 1.3 |
| | [1] | [3] | | [remaining | | | | | |
| | | | | amount] | | | | | |
| Example 21 | (A)-2 | (B)-1 | (C)-1 | (S)-1 | 8.2 | 60 | A | 1.5 | 0.90 |
| | [1] | [2] | [6.5] | [remaining | | | | | |
| | | | | amount] | | | | | |
| Example 22 | (A)-2 | (B)-1 | (C)-1 | (S)-1 | 9.0 | 60 | A | 0.20 | 1.3 |
| | [1] | [2] | [5.5] | [remaining | | | | | |
| | | | | amount] | | | | | |
| Example 23 | (A)-2 | (B)-1 | — | (S)-1 | 10.1 | 60 | A | 2.4 | 3.1 |
| | [1] | [0.2] | | [remaining | | | | | |
| | | | | amount] | | | | | |
| Example 24 | (A)-2 | (B)-2 | — | (S)-1 | 13.0 | 60 | B | 0.40 | 0.50 |
| | [1] | [3] | | [remaining | | | | | |
| | | | | amount] | | | | | |
| Example 25 | (A)-2 | (B)-2 | — | (S)-1 | 13.8 | 60 | A | 0 | 0 |
| | [1] | [10] | | [remaining | | | | | |
| | | | | amount] | | | | | |

As shown in the results listed in Tables 1 and 2, it was confirmed that in a case where the liquid detergents of Examples 1 to 13 and Examples 14 to 25 to which the present invention was applied were used, both the removability of etching residues and the property of reducing damage to metals were satisfactory.

Meanwhile, in a case where the liquid detergents of Comparative Examples 1, 2, 4, 5, 6, and 8 which are outside the scope of the present invention were used, either the removability of the etching residues or the property of reducing damage to metals was inferior.

In addition, in the liquid detergents of Comparative Examples 3 and 7, hydroxylamine was used as the residue remover. In the liquid detergents of Examples 1 to 13 and Examples 14 to 25, the residue removers were replaced with the compound (A), and thus the safety was enhanced.

Hereinbefore, the preferable examples of the present invention have been described, but the present invention is not limited thereto. Additions, omissions, substitutions, and other modifications of configurations can be made without departing from the scope of the present invention. The present invention is not limited by the above description, but only by the appended claims.

### REFERENCE SIGNS LIST

10 Substrate
20 Metal wiring layer
30 Etching stop layer
40 Interlayer insulating film
50 Hard mask layer (HM layer)
60 Dry etching residue
100 Element

What is claimed is:

1. A liquid detergent for removing an etching residue containing an inorganic substance, the liquid detergent comprising:
a compound (A) represented by General Formula (a1); and
at least one base selected from the group consisting of an amine and an ammonium compound other than the compound (A), 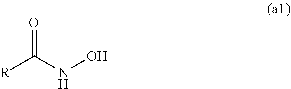
wherein —R represents —NH₂ or —O—C(CH₃)₃.

2. The liquid detergent according to claim 1, wherein a pH measured at 23° C. is 8.0 or greater.

3. The liquid detergent according to claim 1, wherein the base is at least one selected from the group consisting of ammonia, tetramethylammonium hydroxide, tetraethylammonium hydroxide, an alkanolamine, and a triamine.

4. The liquid detergent according to claim 1, wherein a content of the base is in a range of 15 to 5000 parts by mass with respect to 100 parts by mass of the compound (A).

5. The liquid detergent according to claim 1, wherein the liquid detergent is used for cleaning a substrate after dry etching is performed in a wiring process.

6. A method for cleaning a substrate, comprising cleaning a substrate to which an etching residue containing an inorganic substance is attached, using the liquid detergent according to claim 1.

7. The method for cleaning a substrate according to claim 6, wherein cleaning the substrate using the liquid detergent is performed under a condition of 10° C. to 80° C.

8. The method for cleaning a substrate according to claim 6, wherein the substrate is a substrate after dry etching is performed in a wiring process.

9. A method for producing a semiconductor element, comprising cleaning a substrate to which an etching residue containing an inorganic substance is attached, using the liquid detergent according to claim 1.
